(19) United States
(12) Patent Application Publication
(10) Pub. No.: US 2011/0299292 A1
(43) Pub. Date: Dec. 8, 2011

(54) Flexirigid support plate

(75) Inventor: Thomas Preuschl, Sinzing (DE)

(73) Assignee: OSRAM GESELLSCHAFT MIT BESCHRAENKTER HAFTUNG, Muenchen (DE)

(21) Appl. No.: 13/201,870

(22) PCT Filed: Jan. 27, 2010
(86) PCT No.: PCT/EP10/50889

§ 371 Date: Aug. 17, 2011

(30) Foreign Application Priority Data
Feb. 17, 2009 (DE) 102009009288.9

(51) Int. Cl. F21V 21/00; H05K 3/30; H05K 1/00

(52) U.S. Cl. 362/382; 174/254; 29/832

(57) ABSTRACT

In various embodiments, a rigid-flex mounting board for at least one semiconductor light source is provided. The mounting board may include at least one rigid support region configured to mount the at least one semiconductor light source; and a flexible support region, wherein the flexible support region has been produced by thinning of a rigid support region.

The invention relates to a rigid-flex mounting board (“flexirigid support plate”) for at least one semiconductor light source, in particular an LED, a lamp device with at least one rigid-flex mounting board and a method for producing such a lamp device.

EP 1033525 A2 discloses a flexible multiple LED module, in particular for a lamp housing of a motor vehicle, having a plurality of rigid circuit boards consisting e.g. of aluminum which are each connected by one of their main surfaces to a flexible circuit board at a distance from one another, and a plurality of LEDs which are mounted on the flexible circuit board in the region of the rigid circuit boards. The flexible circuit board is generally made of a flexible plastic material. It can consist, for example, of a polyester or polyimide foil. A flexible circuit board, preferably a flexboard, can be glued onto the rigid circuit boards.

The object of the present invention is to provide a particularly inexpensive rigid-flex mounting board and a lamp device having such a rigid-flex mounting board.

This object is achieved by means of a rigid-flex mounting board, a lamp device and a method for producing a lamp device as claimed in the respective independent claim. Preferred embodiments are set out in particular in the dependent claims.

The rigid-flex (i.e. in part comparatively rigid and in part comparatively flexible) mounting board is installed as a mounting board for at least one semiconductor light source. The mounting board has at least one comparatively rigid support region for mounting the at least one semiconductor light source and a comparatively flexible support region, said flexible support region having been produced by thinning or narrowing of a rigid support region. Thinning is understood as meaning a general thickness reduction. The thinned support regions are flexible and therefore designed to be bent at least once or a plurality of times without material failure, while the rigid, unthinned support regions are not designed or intended to be bent. This enables a compact and versatilely shapeable mounting board to be produced from a simply manufacturable basic shape, and one which can be easily populated with components. In particular, complex and comparatively fine flexible structures can be produced in a simple manner, thereby in turn allowing a complex and compact geometrical configuration or arrangement of light sources. Consequently, a compact lamp device can be constructed particularly inexpensively.

Any type of semiconductor light source is basically possible. The semiconductor light source can have one or more semiconductor emitters, in particular light emitting diodes (LEDs). The semiconductor emitter(s) can be individually housed ('individual LED'), or a plurality of semiconductor emitters can be mounted on a common substrate (“submount”), e.g. by populating an AIN substrate with LED chips. The electrical connection of the semiconductor emitters to the submount is advantageously effected by means of chip-level connection types, such as bonding (wire bonding, flip chip bonding) etc., whereas the submount and the individual LED are advantageously electrically contacted by means of conventional connection types such as soldering to the mounting board. In principle, one or more submounts can be mounted on the mounting board or one of the rigid support regions. If a plurality of semiconductor emitters is present, these can emit in the same color, for example white, which makes possible a simple scalability of the brightness. The semiconductor emitters can however at least in part also exhibit a different emission color, for example red (R), green (G), blue (B), amber (A) and/or white (W). By this means, it is where applicable possible to tune an emission color of the light source, and any desired color point can be set. In particular, it may be preferred if semiconductor emitters having different emission colors are able to produce a white mixed light. Instead of or in addition to inorganic light emitting diodes, for example based on InGaN or AlInGaP, organic LEDs (OLEDs) can in general also be used. In general, other semiconductor light sources such as laser diodes can also be used.

The materials of the rigid support region and the flexible support region can be the same, different or partially the same and partially different. For example, the rigid support regions and the flexible support regions can be produced in one piece from the same material, including composite material. However, the rigid support regions and the flexible support regions can also be of completely different materials. Alternatively, the rigid support regions and the flexible support regions may include one or more identical materials and differ by the presence of one or more materials.

It can be advantageous if the support regions have a circuit board base material, in particular a fiberglass/resin composite material, e.g. FR2, FR4, CEM (‘composite epoxy material’) −1, etc. Circuit board material is well known and suitable, available cheaply in large quantities and easy to process. The circuit board base material is preferably implemented in one piece across different support regions.

The thinning preferably includes at least one thinning of the circuit board base material. This means that the thinning advantageously also includes a thinning of the circuit board base material. A volume of another material can likewise be thinned and/or may remain unprocessed. It can be particularly advantageous if the thinned circuit board base material has a minimum residual thickness of between 20 and 50 μm.

It can be particularly advantageous if the circuit board material is a fiberglass/resin composite material, as such a composite material is particularly easy to process, can be laminated as a multilayer system and, as a thin layer, can be bent for a limited number of times without material failure.

For the easily manageable and inexpensive production of flexible support regions it is preferred if at least one rigid support region and an adjacent flexible support region have at least one common layer consisting of the circuit board base material.

Particularly in this case, but also generally, it can be advantageous if the volume to be thinned, in particular the circuit board base material, is manufactured as a multilayer. This can take place, for example, by stacking or laminating of prepregs (‘preimpregnated fibers’), particularly prepregs in the form of continuous fiber reinforced duroplastic semifinished products.

It may be preferable if the support regions have a metal layer or coating, in particular a copper layer (copper cladding), particularly as an outer layer or coating. The copper layer can be, for example, a rolled copper cover tape. This need not cover the whole surface, but can also, for example, be patterned for the electrical wiring. It may be preferred if the metal layer is not affected by the thinning, but remains unprocessed in this respect. By means of the metal layer or coating, bending of a flexible support region with a high plastic deformation portion can be achieved, thereby enabling the bending to be effected with high precision and in a positionally stable manner. For this purpose, when using the metal layer for wiring, the individual traces are made as wide as possible, so that the area covered by the traces becomes as large as possible. Heat spreading and dissipation can also be promoted at least locally by the metal layer. For this purpose also, the individual traces are made as wide as possible. Aluminum, copper or alloys thereof can be used as metals.

The mounting board can be connected to at least one heat sink, e.g. a heat sink can be thermally connected to the metal cover layer.

For electrical connection and/or for heat dissipation of a heat source (light source, driver, etc.) mounted on a rigid support region, at least one rigid support region can have at least one plated-through hole (‘via’ and/or ‘thermal via’). In particular, the via hole can extend from a contact region for the heat source on one side of a rigid support region to a heat distribution layer. The heat distribution layer can be located in particular on the other side (back side or underside) and be constituted e.g. by the copper layer (copper cladding).

The lamp device is fitted with at least one rigid-flex mounting board, at least one semiconductor light source being mounted on at least one rigid-flex mounting board. This enables a lamp device to be provided whose light sources can be inexpensively disposed compactly and in variety of configurations (position, alignment, etc.).

A driver for operating at least one of the semiconductor light sources can preferably be mounted on at least one rigid support region. Electrical leads to the at least one semiconductor light source, and also between semiconductor light sources and between the driver and a power terminal are present and can be routed e.g. via one or more wiring layers, e.g. via a copper layer, e.g. the copper cladding.

For particularly simple mounting of the mounting board on the lamp device it may be preferable if the rigid-flex mounting board is bent at at least one flexible support region such that it is self-supporting, thereby completely or largely obviating the need for supporting elements.

To provide a mounting board that is stable, in particular self-supporting, in the bent state, it can be particularly advantageous if the rigid-flex mounting board is bent at at least one flexible support region to form an at least partially closed body. Said body need not be completely closed. In particular, the rigid-flex mounting board can be bent into a body with an at least partially closed lateral surface, e.g. with an angular, specifically quadrangular, or a round lateral surface.

For secure mounting of a mounting board in the lamp device, a support region, in particular a rigid support region, can be fixed in an encapsulating material (‘molding compound’). For a particularly compact design, a driver element can be mounted on the rigid support region fixed in the encapsulating material.

A lamp device may be preferred which has a rigid-flex mounting board with at least two rigid support regions interconnected by a flexible support region, at least one rigid support region being fixed in an encapsulating material and the other rigid support region being retained by a flexible support region. The position of the at least one rigid support region which is not fixed in the encapsulating material can then be simply adjusted by bending at least one flexible support region.

The rigid-flex mounting board can be used particularly advantageously with a retrofit lamp, the rigid-flex mounting board being at least partly accommodated in a translucent bulb. This enables complex lighting to be produced comparatively inexpensively where space is at a premium. A retrofit lamp may be regarded as a lamp which is used to replace a conventional lamp, e.g. a filament lamp, wherein the at least one semiconductor light source is to be accommodated in an available space corresponding approximately to the space e.g. of a glass bulb of a filament lamp.

The lamp device can be produced by means of a process including at least the following steps: (a) fabricating a rigid mounting board; (b) fabricating a rigid-flex mounting board from the rigid mounting board by producing at least one flexible support region by thinning; (c) populating at least one rigid support region; (d) bending at least one flexible support region; (e) fitting the lamp device with the rigid-flex mounting board, in particular a pre-bent mounting board.

Said sequence of steps need not be as set out above. For example, step (c) can be carried out before step (b). The populating can include the placement of semiconductor light sources and/or electronic components. In step (a), the mounting board can basically be fabricated using all suitable fabrication methods, in particular by means of fabrication processes for producing printed circuit boards.

The thinning (or narrowing) in step (b) can be carried out using all suitable separating methods, e.g. by means of machining methods such as milling, by means of abrading methods such as laser ablation, or by means of dividing methods such as cutting and removal.

The fitting of the lamp device with the bent rigid-flex mounting board in step (e) can alternatively or additionally also take place with the unbent mounting board, wherein the mounting board can then be bent in the fitted state.

Particularly preferred is a method in which the step of fabricating the rigid mounting board includes permanently combining a plurality of individual layers, wherein at least two consecutive coatings or layers are not permanently combined in a region provided as a flexible support region; and the step of producing the rigid-flex mounting board by thinning is carried out by removal of coating regions along the two consecutive, not permanently combined coatings. As a result, the thinning can advantageously be carried out by scribing, slitting, etc. and subsequent removal of at least one layer, said layer not being permanently combined or conjoined with an adjacent layer, e.g. not adhesively bonded or laminated.

The condition of at least two consecutive layers not being permanently combined can be achieved, for example, by not providing adhesive material between two individual layers and/or inserting a non-stick protective foil, e.g. during stacking and prior to pressing.

The invention is described schematically in greater detail in the following figures, wherein, for the sake of clarity, elements which are identical or have the same effect are designated by the same reference characters.

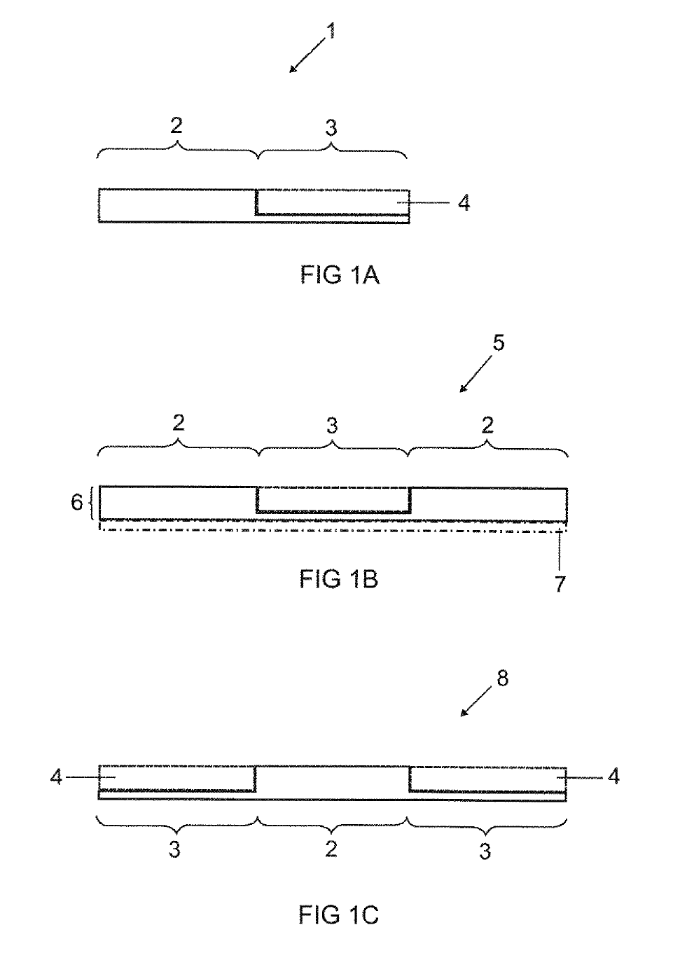

FIG. 1A shows a sectional side view of a rigid-flex mounting board;

FIG. 1B shows a sectional side view of another rigid-flex mounting board;

FIG. 1C shows a sectional side view of yet another rigid-flex mounting board;

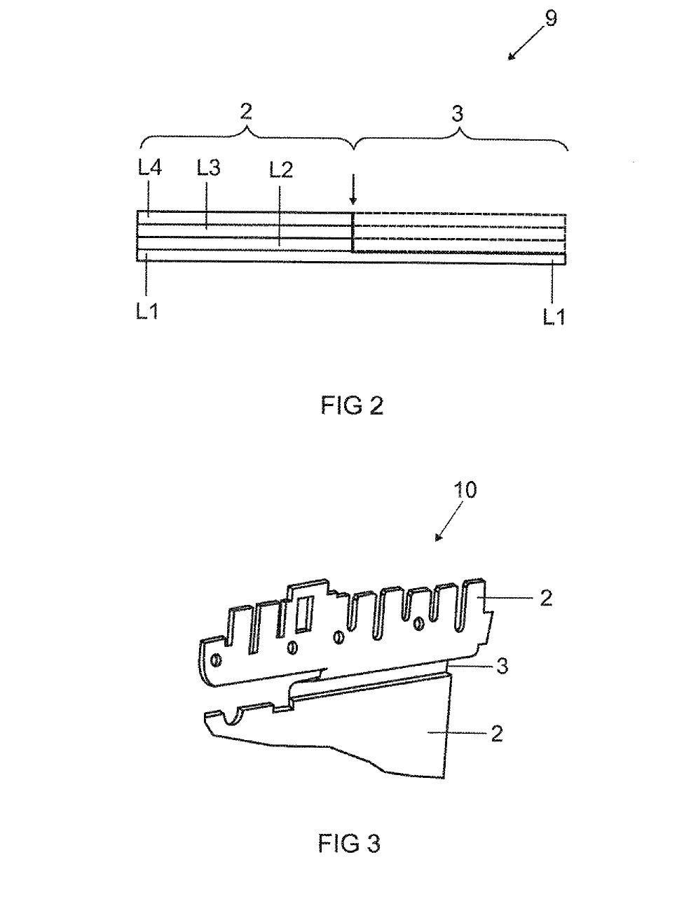

FIG. 2 shows a sectional side view of yet another rigid-flex mounting board;

FIG. 3 shows an oblique view of a detail of a mounting board;

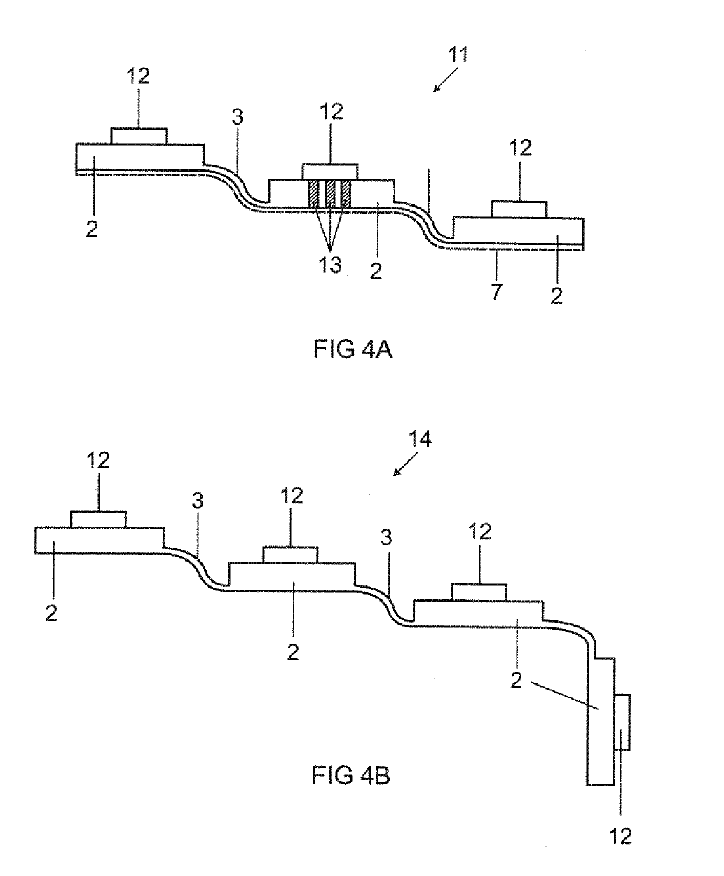

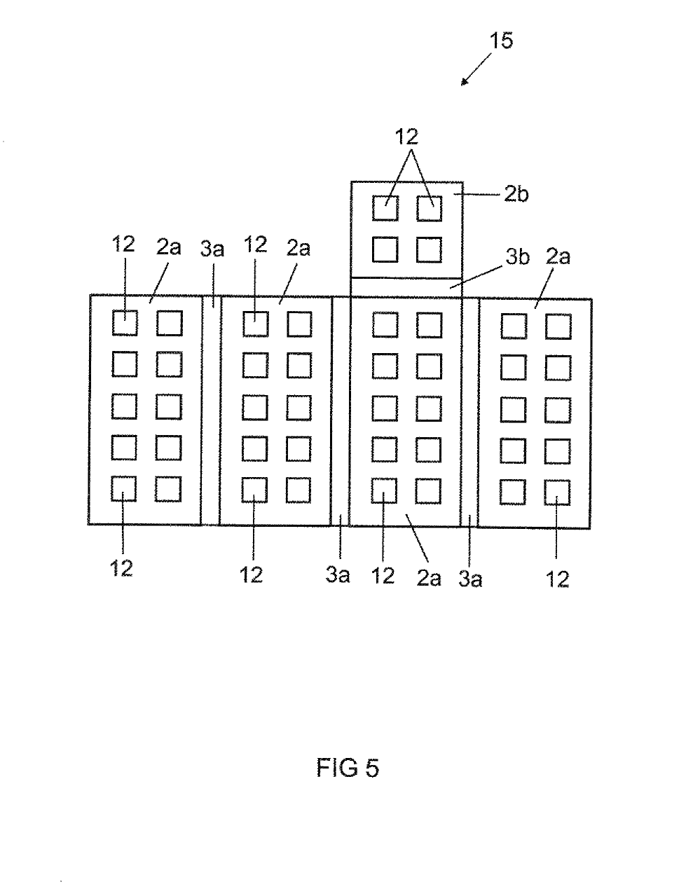

FIG. 4A shows a sectional side view of another rigid-flex mounting board;

FIG. 4B shows a sectional side view of yet another rigid-flex mounting board;

FIG. 5 shows a plan view of a populated upper side of a rigid-flex mounting board in the unbent state;

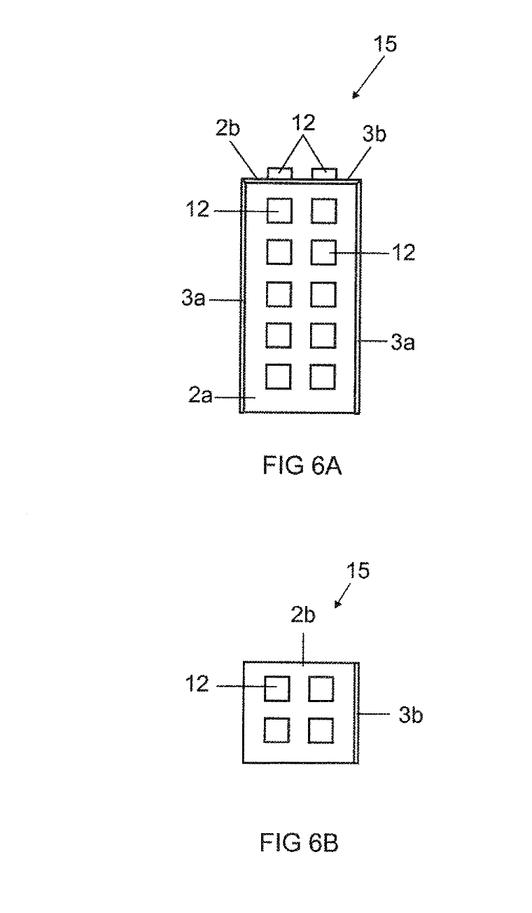

FIG. 6A shows a side view of the rigid-flex mounting board from FIG. 5 in the bent state;

FIG. 6B shows a plan view of the rigid-flex mounting board from FIG. 5 in the bent state;

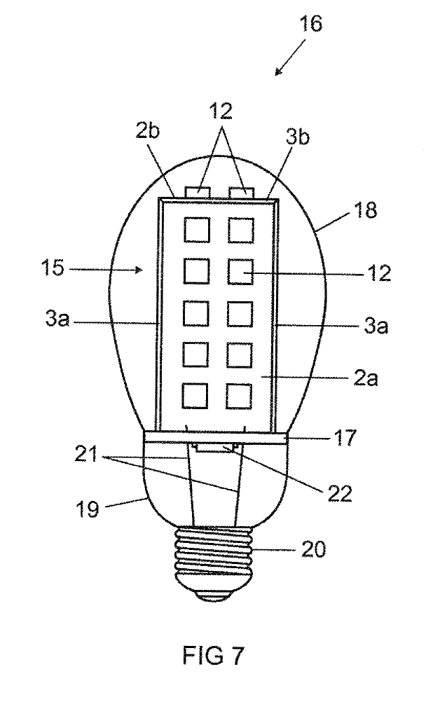

FIG. 7 shows a lamp device with a rigid-flex mounting board according to a first embodiment;

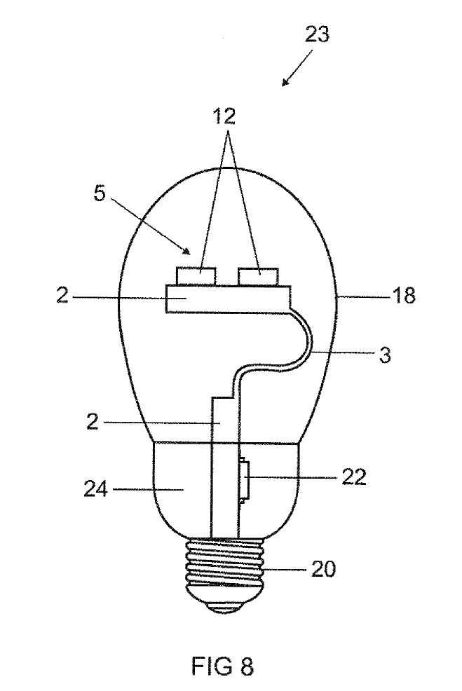

FIG. 8 shows a lamp device with a rigid-flex mounting board according to a second embodiment.

FIG. 1A shows a sectional side view of a rigid-flex mounting board 1, consisting of a circuit board material in the form of a fiberglass/resin composite material, in this case FR4. The mounting board 1 has a comparatively rigid, because thicker, support region 2 and a comparatively flexible or bendable, because thinner, support region 3. Because of the lower thickness of the flexible support region 3, it can be bent at least once without material failure, while the rigid support region 2 can be bent only slightly without material failure. The flexible support region 3 was produced by fabricating an initially uniform rigid FR4 mounting board and thinning or narrowing the flexible support region 3 by milling off a volume 4 indicated here by a dashed line. The thickness of the flexible support region 3 is here approximately 35 μm, the thickness of the rigid support region 2 approximately 210 μm.

FIG. 1B shows a sectional side view of another rigid-flex mounting board 5 which, in contrast to the rigid-flex mounting board 1 from FIG. 1A, has a flexible support region 3 located between two rigid support regions 2. In addition, below the circuit board material 6 (on the back side of the mounting board 5) there is now a copper layer or coating (copper cladding) 7 patterned with wiring traces (indicated by a dash-dotted line). The mounting board 5 is preferably populated on the (front) side opposite the copper layer 7. The copper layer 7 is not thinned. In the extreme case, the circuit board base material can be completely abraded from the flexible support region 3.

The copper layer can be thermally connected to a heat sink (not shown) in order to dissipate heat from the mounting board 5.

FIG. 1C shows a sectional side view of yet another rigid-flex mounting board 8 which, in contrast to the rigid-flex mounting board 1 from FIG. 1A, now has a rigid support region 2 between two flexible support regions 2.

FIG. 2 shows a sectional side view of yet another rigid-flex mounting board 9. The mounting board 9 is now composed of a plurality of similarly structured layers or coatings L1,L2,L3,L4 of FR4 circuit board material (particularly prepregs). More precisely, the rigid support region 2 is made up of four layers L1,L2,L3,L4, while the flexible support region 3 includes only the lowest layer L1. The rigid-flex mounting board 9 was fabricated such that initially a uniform, rigid mounting board was produced by lamination or pressing of the layers L1-L4. In this process, adhesion between the lowest L1 and the overlying layer L2 in the area intended for producing the flexible support region 3 is prevented by inserting a non-stick protective foil. The permanently combined stack including the layers L2 to L4 was subsequently separated, e.g. scribed or slit, at the boundary between the rigid support region 2 and the flexible support region 3, as indicated by the arrow. The coherent stack of layers L2, L3 and L4 was then removed in the area intended for producing the flexible support region 3, leaving only the lowest layer L1.

FIG. 3 shows an oblique view of a detail of a mounting board 10 of complex shape including two rigid support regions 2 and a flexible support region 3. This arrangement enables the two rigid support regions 2 to be angled with respect to one another by bending the flexible support region 3. The bending can be elastic, plastic or elastic-plastic.

FIG. 4A shows a sectional side view of another rigid-flex mounting board 11 of similar design to the mounting boards 1, 5 and 8 from FIGS. 1A to 1C, but now having three rigid support regions 2 which are interconnected by two flexible, thinner support regions 3, i.e. two rigid support regions 2 are each connected by a flexible support region 3. The upper sides of the rigid support regions 2 each contain a light emitting diode 12. For heat dissipation from the LED 12 and/or for electrical contacting of the LED 12, the central rigid support region 2 is provided, for example, with vias 13 which extend through the rigid support region 2 from front to back side. The back side has a copper cladding 7 patterned for electrical wiring and can be connected to a heat sink (not shown here). Heat produced by an LED 12 can therefore be dissipated via the thermal vias 13 to the copper cladding 7 and possibly from there to a heat sink. The flexible support regions 3 are here bent such that the rigid support regions 2 are aligned parallel and (vertically) offset with respect to one another.

FIG. 4B shows a sectional side view of yet another rigid-flex mounting board 14 of similar construction to the mounting board 11 from FIG. 4A, but now having four rigid support regions 2 interconnected by three intervening flexible, thinner support regions 3, i.e. two rigid support regions 2 are each connected by a flexible support region 3. In this arrangement the outer right-hand rigid support region 2 is at right-angles to the adjacent rigid support region 2 because of the bending of the intervening flexible support region 3.

FIG. 5 shows another rigid-flex mounting board 15 in the unbent state in a plan view of a populated upper side. The mounting board 15 has four mutually parallel rigid rectangular support regions 2a which are connected via their longer sides by means of a comparatively narrow flexible support region 3a in each case. An essentially rectangular rigid support region 2b is connected via a narrow flexible support region 3b to a shorter side of one of the rigid support regions 2a. Whereas the larger rectangular rigid support regions 2a are each populated with ten LEDs, the smaller rectangular rigid support region 2b is populated with only four LEDs 12. Adjacent support regions 2a, 2b can be angled to one another e.g. at 90° by bending the support region 3a or 3b connecting them.

FIG. 6A shows the rigid-flex mounting board 15 from FIG. 5 in the bent state in a side view of one of the larger rectangular rigid support regions 2a. The rigid-flex mounting board 15 has been bent at the narrow flexible support regions 3a, 3b through 90° in each case such that the upper sides of the rigid support regions 2a, 2b with the LEDs 12 mounted thereon face outward. This produces a cuboid-shaped mounting board 15 with a small open lower lateral surface, while the opposite small open upper lateral surface is essentially closed by the small rigid support region 2b, as shown in FIG. 6B in a plan view of the bent mounting board 15 or more specifically the support region 2b. The extent of said flexible support regions 3a, 3b is negligible; these constitute the edge regions of the cuboid. Edges not closed by flexible support regions 3a, 3b can be added, e.g. glued on, which increases the strength of the mounting board 15 still further. The mounting board 15 bent into a cuboid shape is self-supporting and can be laid e.g. on the open underside without losing its shape.

FIG. 7 shows a lamp device in the form of a retrofit lamp 16 with the bent rigid-flex mounting board 15 from FIG. 6. The mounting board 15 stands with its open underside on a disk-shaped retainer 17 and is e.g. glued thereon. Because of the self-supporting design of the mounting board 15, it does not require any additional support. Also seated on the retainer 17 is a translucent (transparent or preferably opaque) bulb 18. The retainer 17 is additionally fastened in an e.g. sheet metal retainer receptacle 19 which in turn fits onto a base 20, in particular a filament lamp base such as an Edison screw. Electrical leads 21 extend from the base 20 to the mounting board 15 to supply it, or more specifically the LEDs 12, with power. The retainer 17 is implemented here as a driver board on which at least one driver 22 is mounted to drive the LEDs 12, said driver being inserted between the base 20 and the mounting board 15. The retrofit lamp 16 can be used instead of a conventional filament lamp and does not exceed or does not significantly exceed the overall size of a conventional filament lamp.

FIG. 8 shows a lamp device in the form of a retrofit lamp 23 fitted with the rigid-flex mounting board 5 from FIG. 1B. One of the rigid support regions 2 is here fixed perpendicularly in an encapsulating material 24 with which the retainer receptacle 19 is filled. The driver 22 is disposed on the support region 2 fixed in the encapsulating material 24 such that it is surrounded by the encapsulating material 24. The other rigid support region 2 is at an angle of 90° thereto such that the LEDs 12 face upward. The angular offset of the two rigid support regions 2 relative to one another is achieved by appropriate bending of the flexible support region 3.

The present invention is self-evidently not limited to the exemplary embodiments shown. Thus, the features illustrated in the individual exemplary embodiments can also be combined. For example, in a multilayer design, the mounting board can also have at least one wiring layer disposed between two electrically insulating layers of circuit board base material.

### LIST OF REFERENCE CHARACTERS

1 rigid-flex mounting board
2 rigid support region
2a rigid support region
2b rigid support region
3 flexible support region
3a flexible support region
3b flexible support region
4 volume to be removed
5 rigid-flex mounting board
6 circuit board material
7 external copper layer
8 rigid-flex mounting board
9 rigid-flex mounting board
10 rigid-flex mounting board
11 rigid-flex mounting board
12 light emitting diode
13 via
14 rigid-flex mounting board
15 rigid-flex mounting board
16 retrofit lamp
17 retainer
18 bulb
19 retainer receptacle
20 base
21 electrical lead
22 driver
23 retrofit lamp
24 encapsulating material
L1 bottom layer of a mounting board
L2 layer of a mounting board
L3 layer of a mounting board
L4 top layer of a mounting board

1. A rigid-flex mounting board for at least one semiconductor light source, the mounting board comprising:
at least one rigid support region configured to mount the at least one semiconductor light source;
and a flexible support region,
wherein the flexible support region has been produced by thinning of a rigid support region.

2. The rigid-flex mounting board as claimed in claim 1,
wherein the support regions have a circuit board base material,
wherein the thinning includes thinning of said circuit board base material,

3. The rigid-flex mounting board as claimed in claim 2,
wherein at least one rigid support region and an adjacent flexible support region have at least one common layer of the circuit board base material.

4. The rigid-flex mounting board as claimed in claim 1
wherein at least two support regions have a common copper layer.

5. The rigid-flex mounting board as claimed in claim 1,
wherein at least one rigid support region has at least one via.

6. A lamp device, comprising:
at least one rigid-flex mounting board, comprising:
at least one rigid support region configured to mount the at least one semiconductor light source;
and a flexible support region,
wherein the flexible support region has been produced by thinning of a rigid support region;
wherein at least one semiconductor light source is mounted on at least one rigid-flex mounting board.

7. The lamp device as claimed in claim 6, further comprising:
a driver configured to operate at least one of the semiconductor light sources being mounted on at least one rigid support region.

8. The lamp device as claimed in claim 6, wherein the rigid-flex mounting board is bent at at least one flexible support region such that it is self-supporting.

9. The lamp device as claimed in claim 6,
wherein the rigid-flex mounting board is bent at at least one flexible support region to form an at least partially closed body.

10. The lamp device as claimed in claim 6,
wherein the rigid-flex mounting board with at least two rigid support regions is interconnected by the flexible support region,
wherein at least one rigid support region is fixed in an encapsulating material, and
wherein the other rigid support region is retained by the flexible support region.

11. The lamp device as claimed in claim 10, wherein a driver element is mounted on the rigid support region fixed in the encapsulating material.

12. The lamp device as claimed in claim 6,
wherein the bent rigid-flex mounting board is at least partially accommodated in a translucent bulb.

13. A method for producing a lamp device,
the lamp device comprising:
at least one rigid-flex mounting board, comprising:
at least one rigid support region configured to mount the at least one semiconductor light source;
and a flexible support region,
wherein the flexible support region has been produced by thinning of a rigid support region;
wherein at least one semiconductor light source is mounted on at least one rigid-flex mounting board;
the method comprising:
fabricating a rigid mounting board;
fabricating a rigid-flex mounting board from the rigid mounting board by creating at least one flexible support region by means of thinning;
populating at least one rigid support region;
bending at least one flexible support region;
fitting the lamp device with the rigid-flex mounting board.

14. The method as claimed in claim 13, wherein
the step of fabricating the rigid mounting board includes permanently combining a plurality of individual layers, wherein at least two consecutive coatings or layers are not permanently combined in a region intended as a flexible support region;
the step of fabricating the rigid-flex mounting board by thinning by removal of layer regions along the two consecutive, not permanently combined layers is carried out.

15. The lamp device as claimed in claim 6.
wherein the lamp device is a lamp.

16. The rigid-flex mounting board as claimed in claim 2,
wherein the circuit board base material comprises a fiberglass/resin composite material.

17. The rigid-flex mounting board as claimed in claim 4,
wherein the common copper layer comprises an external copper layer.

18. The lamp device as claimed in claim 9,
wherein the rigid-flex mounting board is bent at at least one flexible support region to form a body with an at least partially closed lateral surface.

19. The lamp device as claimed in claim 12, configured as a retrofit lamp.
